(19) United States
(12) Patent Application Publication
(10) Pub. No.: US 2023/0018706 A1
(43) Pub. Date: Jan. 19, 2023

(54) SOLID-STATE IMAGING DEVICE, METHOD OF MANUFACTURING SOLID-STATE IMAGING DEVICE, AND ELECTRONIC EQUIPMENT

(71) Applicant: SONY SEMICONDUCTOR SOLUTIONS CORPORATION, KANAGAWA (JP)

(72) Inventor: YUICHI YAMAMOTO, KANAGAWA (JP)

(21) Appl. No.: 17/757,476

(22) PCT Filed: Nov. 13, 2020
(86) PCT No.: PCT/JP2020/042399

§ 371 Date: Jun. 16, 2022

(30) Foreign Application Priority Data
Dec. 26, 2019 (JP) 2019-236034

(51) Int. Cl. H01L 27/146

(52) U.S. Cl. CPC H01L 27/1462; H01L 27/14634; H01L 27/14685; H01L 27/1469

(57) ABSTRACT

A solid-state imaging device that can further improve the quality and reliability of the solid-state imaging device is provided. There is provided a solid-state imaging device including: a sensor substrate having an imaging element that generates a pixel signal in a pixel unit; and at least one chip having a signal processing circuit necessary for signal processing of the pixel signal, wherein the sensor substrate and the at least one chip are electrically connected to and stacked on each other, and wherein a protective film is formed on at least a part of a side surface of the at least one chip, the side surface being connected to a surface of the at least one chip on a side on which the at least one chip is stacked on the sensor substrate.

### TECHNICAL FIELD

The present technology relates to a solid-state imaging device, a method of manufacturing a solid-state imaging device, and electronic equipment.

### BACKGROUND ART

Generally, solid-state imaging devices such as complementary metal oxide semiconductor (CMOS) image sensors and charge coupled devices (CCDs) are widely used in digital still cameras, digital video cameras, and the like.

Therefore, in recent years, technological developments for achieving higher quality and higher reliability in a solid-state imaging device have been actively performed. For example, a technology in which a solid-state imaging element and a circuit such as a signal processing circuit or a memory circuit are stacked according to a wafer-on-wafer (WoW) technology for performing joining in a wafer state has been proposed.

### CITATION LIST

### Patent Literature

[PTL 1]

JP 2014-099582 A

### SUMMARY

### Technical Problem

However, in the technology proposed in PTL 1, there is a concern that it is not possible to further improve the quality and reliability of the solid-state imaging device.

Consequently, the present technology is contrived in view of such circumstances, and an object thereof is to provide a solid-state imaging device that can further improve the quality and reliability of a solid-state imaging device and electronic equipment equipped with the solid-state imaging device.

### Solution to Problem

As a result of intensive research to achieve the above-mentioned object, the present inventor has succeeded in further improving the quality and reliability of a solid-state imaging device and has completed the present technology.

That is, in the present technology, there is provided a solid-state imaging device including: a sensor substrate having an imaging element that generates a pixel signal in a pixel unit; and at least one chip having a signal processing circuit necessary for signal processing of the pixel signal, wherein the sensor substrate and the at least one chip are electrically connected to and stacked on each other, and wherein a protective film is formed on at least a part of a side surface of the at least one chip, the side surface being connected to a surface of the at least one chip on a side on which the at least one chip is stacked on the sensor substrate.

In the solid-state imaging device according to the present technology, the protective film may be formed to cover the sensor substrate in a region which is on a side of the at least one chip on which the at least one chip is stacked on the sensor substrate and in which the sensor substrate and the at least one chip are not stacked on each other.

In the solid-state imaging device according to the present technology, the protective film may be formed to cover an outer periphery of the at least one chip in a plan view from a side of the at least one chip.

In the solid-state imaging device according to the present technology, the at least one chip may be constituted by a first chip and a second chip, the first chip and the sensor substrate may be electrically connected to and stacked on each other, the second chip and the sensor substrate may be electrically connected to and stacked on each other, a protective film may be formed on at least a part of a side surface of the first chip, the side surface being connected to a surface of the first chip on a side on which the first chip is stacked on the sensor substrate, and a protective film may be formed on at least a part of a side surface of the second chip, the side surface being connected to a surface of the second chip on a side on which the second chip is stacked on the sensor substrate.

In the solid-state imaging device according to the present technology, the first chip and the second chip may be stacked in the same direction on the sensor substrate, and the protective film may be formed to cover the sensor substrate in a region which is on a side of the first chip on which the first chip is stacked on the sensor substrate, which is on a side of the second chip on which the second chip is stacked on the sensor substrate, in which the sensor substrate and the first chip are not stacked on each other, and in which the sensor substrate and the second chip are not stacked on each other.

In the solid-state imaging device according to the present technology, the first chip and the second chip may be stacked in the same direction on the sensor substrate, and the protective film may be formed to cover an outer periphery of the first chip and an outer periphery of the second chip in a plan view from a side of the first chip and a side of the second chip.

In the solid-state imaging device according to the present technology, the first chip and the second chip may be stacked in the same direction on the sensor substrate, the protective film may be formed in a region which is on a side of the first chip on which the first chip is stacked on the sensor substrate, which is on a side of the second chip on which the second chip is stacked on the sensor substrate, and which is between the first chip and the second chip, and the region on which the protective film is formed may be rectangular in a cross-sectional view from a side of the first chip and a side of the second chip.

In the solid-state imaging device according to the present technology, the first chip and the second chip may be stacked in the same direction on the sensor substrate, the protective film may be formed in a region which is on a side of the first chip on which the first chip is stacked on the sensor substrate, which is on a side of the second chip on which the second chip is stacked on the sensor substrate, and which is between the first chip and the second chip, and the region on which the protective film is formed may have a reversely tapered shape in a cross-sectional view from a side of the first chip and a side of the second chip.

In the solid-state imaging device according to the present technology, the protective film may be formed by a single film formation.

In the solid-state imaging device according to the present technology, the protective film may contain a material having an insulating property.

In the solid-state imaging device according to the present technology, the protective film may contain silicon nitride.

Further, in the present technology, there is provided electronic equipment equipped with the solid-state imaging device according to the present technology.

Furthermore, in the present technology, there is provided a method of manufacturing a solid-state imaging device including at least: stacking a sensor substrate having an imaging element that generates a pixel signal in a pixel unit and at least one chip having a signal processing circuit necessary for signal processing of the pixel signal to be electrically connected to each other; forming a protective film to cover the at least one chip after the stacking; and thinning the at least one chip from a second surface of the at least one chip opposite a first surface of the at least one chip on a side on which the at least one chip is stacked on the sensor substrate to remove the protective film on the second surface.

The method of manufacturing a solid-state imaging device according to the present technology may further include forming the protective film to cover the at least one chip and the sensor substrate after the stacking.

According to the present technology, it is possible to further improve the quality and reliability of the solid-state imaging device. The effects described here are not necessarily limited and may be any of the effects described in the present disclosure.

### [BRIEF DESCRIPTION OF DRAWINGS]

FIG. 1 is a diagram for illustrating a solid-state imaging device and a method of manufacturing a solid-state imaging device according to a first embodiment to which the present technology is applied.

FIG. 2 is a diagram for illustrating the solid-state imaging device and the method of manufacturing a solid-state imaging device according to the first embodiment to which the present technology is applied.

FIG. 3 is a diagram for illustrating the solid-state imaging device and the method of manufacturing a solid-state imaging device according to the first embodiment to which the present technology is applied.

FIG. 4 is a diagram for illustrating the solid-state imaging device and the method of manufacturing a solid-state imaging device according to the first embodiment to which the present technology is applied.

FIG. 5 is a diagram for illustrating the solid-state imaging device and the method of manufacturing a solid-state imaging device according to a second embodiment to which the present technology is applied.

FIG. 6 is a diagram showing a configuration example of a solid-state imaging device formed by performing stacking using a wafer-on-wafer (WoW) technology.

FIG. 7 is a diagram for explaining a yield.

FIG. 8 is a diagram showing a configuration example of a solid-state imaging device formed by a bump connection.

FIG. 9 is a diagram for explaining contamination of the solid-state imaging device with dust.

FIG. 10 is a diagram showing a usage example of the solid-state imaging devices according to the first and second embodiments to which the present technology is applied.

FIG. 11 is a functional block diagram of an example of electronic equipment according to a third embodiment to which the present technology is applied.

FIG. 12 is a diagram showing an example of a schematic configuration of an endoscopic surgery system.

FIG. 13 is a block diagram showing an example of a functional configuration of a camera head and a CCU.

FIG. 14 is a block diagram showing an example of a schematic configuration of a vehicle control system.

FIG. 15 is an explanatory diagram showing an example of installation positions of a vehicle exterior information detection unit and an imaging unit.

### DESCRIPTION OF EMBODIMENTS

Hereinafter, preferred embodiments for implementing the present technology will be described. The embodiments which will be described below show an example of a representative embodiment of the present technology, and the scope of the present technology should not be narrowly interpreted on the basis of this. In the drawings, unless otherwise specified, “up” means the upper direction or the upper side in the drawing, “down” means the lower direction or the lower side in the drawing, “left” means the left direction or the left side in the drawing, and “right” means the right direction or the right side in the drawing. Further, in the drawings, the same or equivalent elements or members are denoted by the same reference numerals and signs, and repeated description will be omitted.

The description will be made in the following order.

1. Outline of the Present Technology

2. First Embodiment (Example 1 of Solid-state Imaging Device and Example 1 of Method of Manufacturing Solid-state Imaging Device)

3. Second Embodiment (Example 2 of Solid-state Imaging Device and Example 2 of Method of Manufacturing Solid-state Imaging Device)

4. Third Embodiment (Example of Electronic Equipment)

5. Usage Example of Solid-state Imaging Device to Which the Present Technology Is Applied

6. Application Example to Endoscopic Surgery System

7. Application Example to Moving Body

### 1. Outline of the Present Technology

First, an outline of the present technology will be described.

Solid-state imaging devices have achieved high image quality in the forms of a high vision function, a 4k×2k super high vision function, and a super slow motion function, and along with this, a solid-state imaging device has a large number of pixels, a high frame rate, and high gradation. A transmission rate is the number of pixels×the frame rate×the gradation, for example, and thus in a case where the number of pixel is 4k×2k=8M, the frame rate is 240 f/s, and the gradation is 14 bits, the transmission rate becomes 8M×240 f/s×14 bits=26 Gbps.

After signal processing in a stage after a solid-state imaging element, due to an output of RGB in color coordination, higher speed transmission of 26 G×3=78 Gbps is required. If high-speed transmission is performed with a small number of connection terminals, a signal rate per connection terminal becomes high, the difficulty of matching the impedance of a high-speed transmission path increases, the clock frequency increases, and loss also increases, and thus power consumption increases.

In order to avoid this, it is preferable to increase the number of connection terminals for dividing the transmission and slowing down the signal rate. However, increasing the number of connection terminals involves arranging terminals necessary for connection between the solid-state imaging element, a signal processing circuit in the subsequent stage, a memory circuit, and the like, and thus a package of each circuit becomes large. In addition, an electrical wiring substrate required for this is also required to have a stacked wiring with a finer wiring density, a wiring path length becomes longer, and the power consumption increases accordingly.

As the package of each circuit becomes larger, the substrate itself to be mounted also becomes larger, and finally a camera itself equipped with the solid-state imaging device becomes larger.

As a solution, there is a technology in which a solid-state imaging element and a circuit such as a signal processing circuit or a memory circuit are stacked according to a wafer-on-wafer (WoW) technology for performing joining in a wafer state. According to this, semiconductors can be connected with many fine wirings, the number of connection terminals increases, the transmission speed per wiring becomes low, and power consumption can be suppressed. However, in the case of the technology of stacking according to a wafer-on-wafer (WoW) technology, there is no problem as long as chips of wafers to be stacked are the same size, but if the sizes of the chips constituting the wafers are different, the size of the chip having a small chip size with respect to the chip having a large chip size should be matched to the largest chip size, resulting in poor profitability and cost increase.

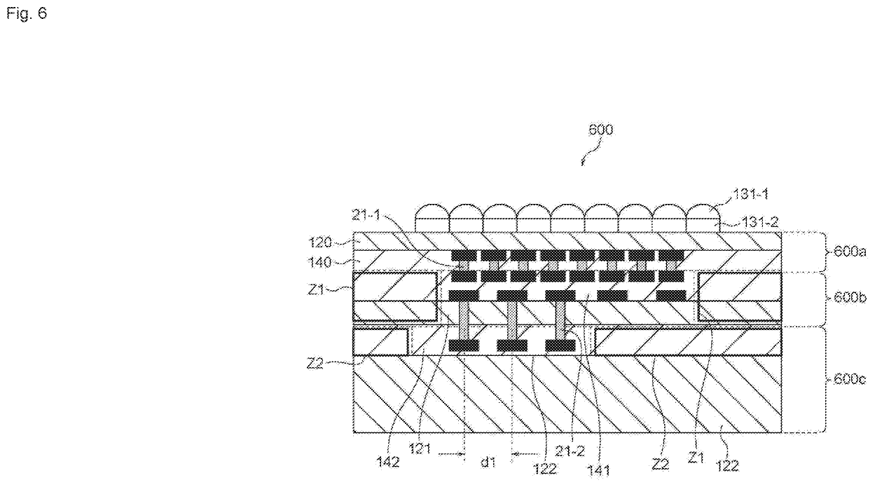

This will be described specifically and in detail with reference to FIG. 6. FIG. 6 is a diagram showing a solid-state imaging device 600 formed by performing stacking using a wafer-on-wafer (WoW) technology.

In the solid-state imaging device 600 shown in FIG. 6, from above (from a light incidence side), an on-chip lens 131-2, a color filter 131-2, a solid-state imaging element 120, a wiring layer 140, a wiring layer 141, a memory circuit 121, a wiring layer 142, and a logic circuit 122 are stacked in that order. Here, a sensor substrate 600a includes the solid-state imaging element 120 and the wiring layer 140, a memory circuit chip 600b includes the memory circuit 121 and the wiring layer 141, and a logic circuit chip 600c includes the logic circuit 122 and the wiring layer 142.

Here, by applying the WoW technology, in wirings 21-1 that electrically connect the sensor substrate 600a and the memory circuit chip 600b to each other, and wirings 21-2 that electrically connect the memory circuit chip 600b and the logic circuit chip 600c to each other, connection at a fine pitch is possible.

As a result, the number of wirings can be increased, and thus the transmission speed in each signal line can be reduced, and it is possible to save power.

However, since the areas required for the stacked sensor substrate 600a, memory circuit chip 600b, and logic circuit chip 600c are different, a space Z1 in which neither a circuit nor a wiring is formed is generated on each of the left and right sides of the memory circuit chip 600b having an area smaller than that of the largest sensor substrate 600a in the drawing. Further, a space Z2 in which neither a circuit nor a wiring is formed is generated on each of the left and right sides of the logic circuit chip 600c having an area smaller than that of the memory circuit chip 600b in the drawing.

That is, the spaces Z1 and Z2 are generated due to the different areas required for the sensor substrate 600a, the memory circuit chip 600b, and the logic circuit chip 600c, and in FIG. 6, stacking is performed with the sensor substrate 600a (the solid-state imaging element 120), which requires the largest area, as a reference, and as a result, the spaces Z1 and Z2 are generated.

Accordingly, the profitability related to the manufacture of the solid-state imaging device 600 is reduced, and as a result, the cost related to the manufacture is increased.

In the yield of each wafer to be stacked, a defect in the chip (the substrate) constituting each wafer is treated as a defect in the chip or the substrate constituting another wafer to be stacked, and the yield of the wafer in the entire stack is a product (multiplication) of the yields of the wafers, resulting in yield deterioration and cost increase.

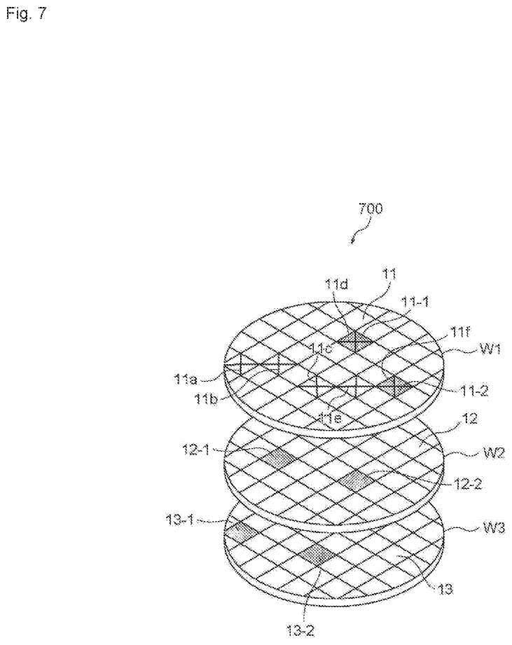

This will be described specifically and in detail with reference to FIG. 7. FIG. 7 is a diagram for explaining a yield.

In FIG. 7, in a solid-state imaging device 700, among a sensor substrate (which may be a sensor chip) 11 including a solid-state imaging element, a memory circuit chip 12 including a memory circuit, and a logic circuit chip 13 including a logic circuit, which are formed on wafers W1 to W3, a defective configuration is represented by being filled with a mesh. That is, in FIG. 7, the wafer W1 has defects in two sensor substrates 11-1 and 11-2, the wafer W2 has defects in two memory chips 12-1 and 12-2, and the wafer W3 has defects in two memory chips 13-1 and 13-2.

As shown in FIG. 7, defects that occur in the sensor substrate 11, the memory circuit chip 12, and the logic circuit chip formed on the wafers W1 to W3 do not necessarily occur at the same position. Therefore, as shown in FIG. 7, in the solid-state imaging device 700 formed by being stacked, six defects (indicated by lla to 110 marked with a cross on the wafer W1 occur.

As a result, with respect to the solid-state imaging device 700 having six defects, at least two of the three components, that is, the sensor substrate 11, the memory circuit chip 12, and the logic circuit chip 13, are not defective, but each is treated as having six defects. Therefore, for each component, originally, the number of the yield is two, but the number of the yield becomes six after being multiplied by the number of wafers.

As a result, the yield of the solid-state imaging device 700 decreases and the manufacturing cost increases.

Another solution is a technology for connecting objects of different sizes to each other by forming bumps. Since chips of different sizes which are selected as non-defective products or the chip and the substrate of different sizes which are selected as non-defective products are connected to each other via the bumps, there is no influence on a profitability difference between the wafers and a yield of each chip or the substrate. However, since it is difficult to form small bumps and a connection pitch is limited, the number of connection terminals is not larger than that in the WoW technology. In addition, when the number of connection terminals is large, the cost increases due to the decrease in yield due to joining because the connection is made in a mounting process, and the connection in the mounting process is also joined individually, and thus the time is long and the process cost increases.

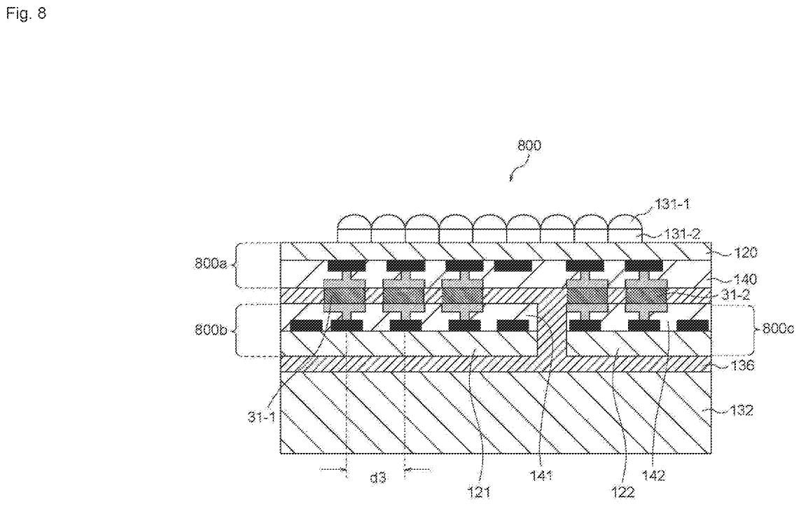

This will be described specifically and in detail with reference to FIG. 8. FIG. 8 is a diagram showing a solid-state imaging device 800 formed by a bump connection.

As shown in FIG. 8, after a sensor substrate 800a, a memory circuit chip 800b, and a logic circuit chip 800c of different sizes are separated into individual pieces, only non-defective products are selectively arranged and connected to each other by forming bumps 31.

In the solid-state imaging device 800 shown in FIG. 8, from above (from a light incidence side), the on-chip lens 131-1, the color filter 131-2, and the sensor substrate 800a are stacked, below them, the memory circuit chip 800b and the logic circuit chip 800c are stacked on the same layer, and below them, a support substrate 132 is provided to be stacked. The sensor substrate 800a includes the solid-state imaging element 120 and the wiring layer 140, the memory circuit chip 800b includes the memory circuit 121 and the wiring layer 141, and the logic circuit chip 800c includes the logic circuit 122 and the wiring layer 142. The sensor substrate 800a (the wiring layer 140) and the memory circuit chip 800b (the wiring layer 141) are electrically connected to each other via bumps 31-1 and the sensor substrate 800a (the wiring layer 140) and the logic circuit chip 800c (the wiring layer 142) are electrically connected to each other via bumps 31-2.

In the solid-state imaging device 800 of FIG. 8, the sensor substrate 800a and the memory circuit chip 800b of different sizes which are selected as non-defective products are connected to each other via bumps 31-1, and the sensor substrate 800a and the logic circuit chip 800c of different sizes which are selected as non-defective products are connected to each other via the bumps 31-2, and thus the influence on the profitability difference between the wafers and the yield of the substrate or each chip is reduced.

However, it is difficult to form the bumps 31 (the bumps 31-1 and the bumps 31-2), and as shown in FIG. 8, there is a limit in reducing a connection pitch d3. Therefore, it is not possible to make the connection pitch d3 smaller than the connection pitch dl of FIG. 6 in the case where the WoW technology is used.

Therefore, the solid-state imaging device 800 of FIG. 8 stacked using the bumps 31 (the bumps 31-1 and the bumps 31-2) cannot have a larger number of connection terminals than the solid-state imaging device 6 of FIG. 6 which is stacked according to the WoW technology. Further, in the case of connection using the bumps as in the solid-state imaging device 800 of FIG. 8, when the number of connection terminals is large, the joining is performed in the mounting process, and thus the yield related to the joining decreases and the cost increases. Furthermore, since the bump connection in the mounting process is also an individual task, each process takes a long time and the process cost also increases.

As described above, the technology for connecting a high-speed transmission signal output from a solid-state imaging device having the high quality and high frame rate to a processing circuit in a subsequent stage such as a logic circuit or a memory circuit may be extremely costly.

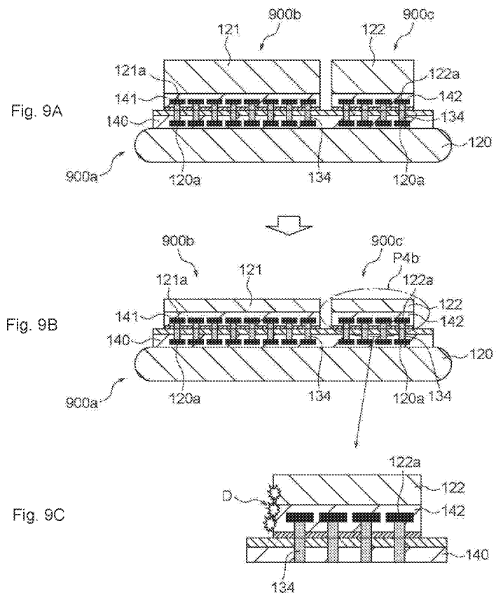

Next, contamination of the circuit chips (the signal processing circuit chips) such as the memory circuit chip and the logic circuit chip joined (connected) to the sensor substrate during thin processing will be described with reference to FIG. 9. FIG. 9 is a diagram for explaining contamination of the solid-state imaging device with contaminants (for example, dust, metal contaminants, and the like).

As shown in FIG. 9(a), a sensor substrate 900a including the solid-state imaging element 120 and the wiring layer 140 and a first chip 900b (a memory circuit chip 900b in FIG. 9) including a signal processing circuit (a memory circuit in FIG. 9) 121 and the wiring layer 141 are electrically connected to each other, and the sensor substrate 900a including the solid-state imaging element 120 and the wiring layer 140 and a second chip 900c (a logic circuit chip 900c in FIG. 9) including a signal processing circuit (a logic circuit in FIG. 9) 122 and the wiring layer 142 are electrically connected to each other.

Specifically, wirings 120a formed in the wiring layer 140 of the sensor substrate 900a and wirings 121a formed in the wiring layer 141 of the memory circuit chip 900b are electrically connected to each other by wirings 134 connected in Cu-Cu (copper-copper) connection, and the wirings 120a formed in the wiring layer 140 of the sensor substrate 900a and wirings 122a formed in the wiring layer 142 of the logic circuit chip 900c are electrically connected to each other by the wirings 134 connected in Cu-Cu (copper-copper) connection.

As shown in FIG. 9(b), from a second surface of the memory circuit chip 900b opposite a first surface of the memory circuit chip 900b on a side on which the memory circuit chip 900b is stacked on the sensor substrate 900a and a second surface of the logic circuit chip 900c opposite a first surface of the logic circuit chip 900c on a side on which the logic circuit chip 900c is stacked on the sensor substrate 900a, a semiconductor substrate that constitutes the memory circuit 121 and a semiconductor substrate that constitutes the logic circuit 122 are thinned and further flattened. In addition, thinning the semiconductor substrate that constitutes the memory circuit 121 and the semiconductor substrate that constitutes the logic circuit 122 means that the semiconductor substrate that constitutes the memory circuit 121 and the semiconductor substrate that constitutes the logic circuit 122 are scraped to reduce the thickness.

FIG. 9(c) is an enlarged cross-sectional view of a portion P4b shown in FIG. 9(b). Contaminants D (for example, dust and metal contaminants) may adhere to the logic chip 100c (the logic circuit 122 and the wiring layer 142), and it may not be possible to prevent contamination of the logic chip 100c.

The present technology is contrived in view of the above-described circumstances. According to the present technology, by covering the chips with a protective film (for example, a SiN film) and thinning the chips after a chip-on-wafer (CoW) technology, it is possible to prevent contamination of each chip at the time of thinning.

The present technology mainly relates to a solid-state imaging device and a method of manufacturing a solid-state imaging device. The solid-state imaging device according to the present technology is a solid-state imaging device including: a sensor substrate having an imaging element that generates a pixel signal in a pixel unit; and at least one chip having a signal processing circuit necessary for signal processing of the pixel signal, wherein the sensor substrate and the at least one chip are electrically connected to and stacked on each other, and wherein a protective film (for example, a silicon nitride film) is formed on at least a part of a side surface of the at least one chip, the side surface being connected to a surface of the at least one chip on a side on which the at least one chip is stacked on the sensor substrate. Further, the method of manufacturing a solid-state imaging device according to the present technology is a method of manufacturing a solid-state imaging device including at least: stacking a sensor substrate having an imaging element that generates a pixel signal in a pixel unit and at least one chip having a signal processing circuit necessary for signal processing of the pixel signal to be electrically connected to each other; forming a protective film to cover the at least one chip after the stacking; and thinning the at least one chip from a second surface of the at least one chip opposite a first surface of the at least one chip on a side on which the at least one chip is stacked on the sensor substrate to remove the protective film on the second surface.

Hereinafter, preferred embodiments for implementing the present technology will be described in detail with reference to the drawings. The embodiments which will be described below show an example of a representative embodiment of the present technology, and the scope of the present technology should not be narrowly interpreted on the basis of this.

### 2. First Embodiment (Example 1 of Solid-state Imaging Device and Example 1 of Method of Manufacturing Solid-state Imaging Device)

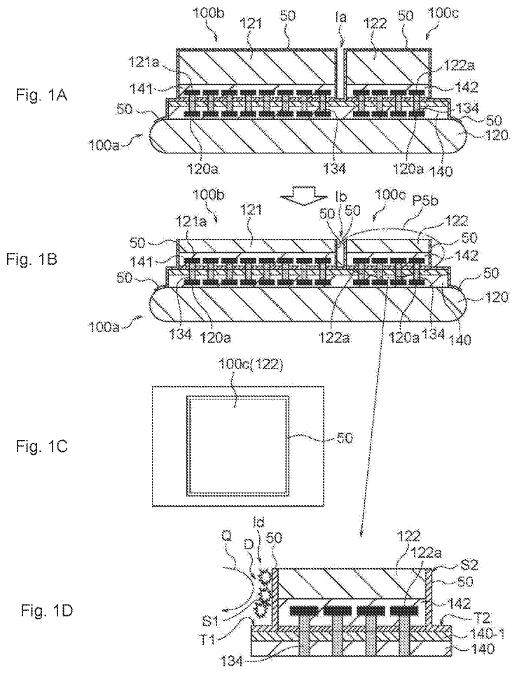

A solid-state imaging device and a method of manufacturing a solid-state imaging device of a first embodiment according to the present technology (Example 1 of the solid-state imaging device and Example 1 of the method of manufacturing a solid-state imaging device) will be described with reference to FIGS. 1 to 4.

First, description will be made using FIG. 1. FIG. 1 is a diagram for illustrating a solid-state imaging device and a method of manufacturing a solid-state imaging device of the first embodiment according to the present technology.

As shown in FIG. 1(a), a sensor substrate 100a including a solid-state imaging element 120 and a wiring layer 140 and a first chip 100b (a memory circuit chip 100b in FIG. 1) including a signal processing circuit (a memory circuit in FIG. 1) 121 and a wiring layer 141 are electrically connected to each other, and the sensor substrate 100a including the solid-state imaging element 120 and the wiring layer 140 and a second chip 100c (a logic circuit chip 100c in FIG. 1) including a signal processing circuit (a logic circuit in FIG. 1) 122 and a wiring layer 142 are electrically connected to each other.

Specifically, wirings 120a formed in the wiring layer 140 of the sensor substrate 100a and wirings 121a formed in the wiring layer 141 of the memory circuit chip 100b are electrically connected to each other by wirings 134 connected in Cu-Cu (copper-copper) connection, and the wirings 120a formed in the wiring layer 140 of the sensor substrate 100a and wirings 122a formed in the wiring layer 142 of the logic circuit chip 100c are electrically connected to each other by the wirings 134 connected in Cu-Cu (copper-copper) connection.

Then, a protective film 50 (a SiN film 50 in FIG. 1) is formed to cover the sensor substrate 100a, the memory circuit chip 100b, and the logic circuit chip 100c. Although the SiN film 50 is used in FIG. 1, as long as a material of the protective film 50 has an insulating property and functions as a stopper for contamination with contaminants such as metal contaminants and dust at the time of thinning, which will be described later, the material of the protective film 50 is not limited and may be anything.

A region (an opening) Ia that is on a side of the memory circuit chip 100b stacked on the sensor substrate 100a, on a side of the logic circuit chip 100c stacked on the sensor substrate 100a, and between the memory circuit chip 100b and the logic circuit chip 100c has a rectangular shape in a cross-sectional view (in the region (the opening) Ia shown in FIG. 1(a), a length of an upper side and a length of a lower side are substantially the same). The SiN film 50 is embedded in the region (the opening) Ia.

As shown in FIG. 1(b), from a second surface of the memory circuit chip 100b opposite a first surface of the memory circuit chip 100b on a side on which the memory circuit chip 100b is stacked on the sensor substrate 100a and a second surface of the logic circuit chip 100c opposite a first surface of the logic circuit chip 100c on a side on which the logic circuit chip 100c is stacked on the sensor substrate 100a, a semiconductor substrate that constitutes the memory circuit 121 and a semiconductor substrate that constitutes the logic circuit 122 are thinned and further flattened, and the SiN films 50 on the second surface of the memory circuit chip 100b and on the second surface of the logic circuit chip 100c are removed. In addition, thinning the semiconductor substrate that constitutes the memory circuit 121 and the semiconductor substrate constituting the logic circuit 122 means that the semiconductor substrate that constitutes the memory circuit 121 and the semiconductor substrate that constitutes the logic circuit 122 are scraped to reduce the thickness.

Therefore, the SiN films 50 are formed on left and right side surfaces of the memory circuit chip 100b connected to the surface of the memory circuit chip 100b on a side on which the memory circuit chip 100b is stacked on the sensor substrate 100a and on left and right side surfaces of the logic circuit chip 100c connected to the surface of the logic circuit chip 100c on a side on which the logic circuit chip 100c is stacked on the sensor substrate 100a. Then, the SiN film 50 is formed to cover the sensor substrate 100a in a region which is on a side of the memory circuit chip 100b on which the memory circuit chip 100b is stacked on the sensor substrate 100a, which is on a side of the logic circuit chip 100c on which the logic circuit chip 100c is stacked on the sensor substrate 100a, in which the sensor substrate 100a and the memory circuit chip 100b are not stacked on each other, and in which the sensor substrate 100a and the logic circuit chip 100c are not stacked on each other.

The SiN film 50 is embedded in a region (an opening) Ib that is on a side of the memory circuit chip 100b stacked on the sensor substrate 100a, on a side of the logic circuit chip 100c stacked on the sensor substrate 100a, and between the memory circuit chip 100b and the logic circuit chip 100c, and the region in which the SiN film 50 is formed has a rectangular shape in a cross-sectional view. That is, the SiN film 50 in the region (the opening) Ib includes a SiN film formed on the right side surface of the memory circuit chip 100b, a SiN film formed on the left side surface of the logic circuit chip 100c, and a SiN film formed to cover the sensor substrate 100a in a region between the right side surface of the memory circuit chip 100b and the left surface of the logic circuit chip 100c.

FIG. 1(c) is a top view from a side of the logic circuit chip 100c (the logic circuit 122). As shown in FIG. 1(c), the SiN film 50 is formed to cover an outer periphery of the logic circuit chip 100c and can prevent contamination of the logic circuit chip 100c at the time of thinning. Incidentally, although not shown, the same applies to the memory circuit chip 100b, and the SiN film 50 is formed to cover the outer periphery of the memory circuit chip 100b and can prevent contamination of the memory circuit chip 100b at the time of thinning.

FIG. 1(d) is an enlarged cross-sectional view of a portion P5b shown in FIG. 1(b). The SiN film 50 is formed on a left side surface S1 and a right side surface S2 of the logic circuit chip 100c, and the SiN film 50 is formed to cover the wiring layer 140 and an insulating film 140-1 (for example, an oxide film) of the sensor substrate 100a (in FIG. 1(d), the SiN film 50 is formed on the wiring layer 140 and the insulating film 140-1 of the sensor substrate 100a). Due to the formation of the SiN film 50, the contaminants D (for example, dust and metal contaminants) on a right wall side of the opening Ic are kept away from the logic chip 100c as shown with a direction of an arrow Q, and the contamination of the logic chip 100c is prevented.

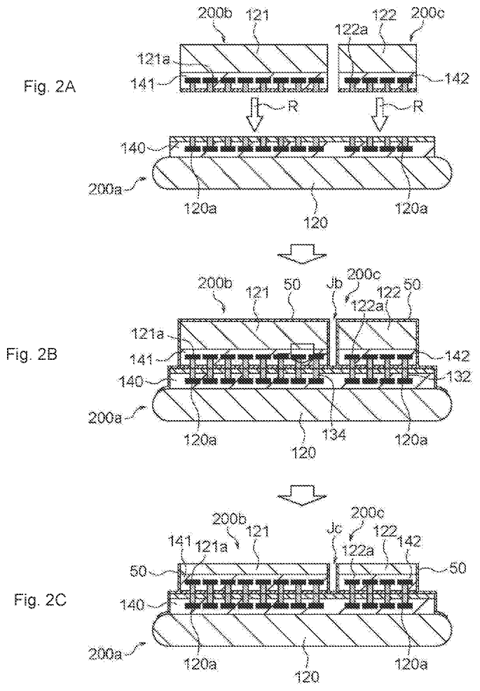

Next, description will be made using FIG. 2. FIG. 2 is a diagram for illustrating the solid-state imaging device and the method of manufacturing a solid-state imaging device of the first embodiment according to the present technology.

FIG. 2(a) shows a state before a sensor substrate 200a including a solid-state imaging element 120 and a wiring layer 140 and a first chip 200b (a memory circuit chip 200b in FIG. 2) including a signal processing circuit (a memory circuit in FIG. 2) 121 and a wiring layer 141 are joined to each other in Cu-Cu (copper copper) joining and shows a state before the sensor substrate 200a including the solid-state imaging element 120 and the wiring layer 140 and a second chip 200c (a logic circuit chip 200c in FIG. 2) including a signal processing circuit (a logic circuit in FIG. 2) 122 and a wiring layer 142 are joined to each other in Cu-Cu (copper-copper) joining. As shown in FIG. 2(a), the sensor substrate 200a and the memory circuit chip 200b are joined to each other in a direction of an arrow R, and similarly, the sensor substrate 200a and the logic circuit chip 200c are joined to each other in the direction of the arrow R.

As shown in FIG. 2(b), the sensor substrate 200a including the solid-state imaging element 120 and the wiring layer 140 and the first chip 200b (the memory circuit chip 200b in FIG. 2) including the signal processing circuit (the memory circuit in FIG. 2) 121 and the wiring layer 141 are electrically connected to each other, and the sensor substrate 200a including the solid-state imaging element 120 and the wiring layer 140 and the second chip 200c (the logic circuit chip 200c in FIG. 2) including a signal processing circuit (the logic circuit in FIG. 2) 122 and the wiring layer 142 are electrically connected to each other.

Specifically, wirings 120a formed in the wiring layer 140 of the sensor substrate 200a and wirings 121a formed in the wiring layer 141 of the memory circuit chip 200b are electrically connected to each other by wirings 134 connected in Cu-Cu (copper-copper) connection, and the wirings 120a formed in the wiring layer 140 of the sensor substrate 200a and wirings 122a formed in the wiring layer 142 of the logic circuit chip 100c are electrically connected to each other by the wirings 134 connected in Cu-Cu (copper-copper) connection.

Then, after the sensor substrate 200a, the memory circuit chip 200b, and the logic chip 200c are joined to each other, the protective film 50 (the SiN film 50 in FIG. 2) is formed to cover the sensor substrate 100a, the memory circuit chip 100b, and the logic circuit chip 100c. The SiN film 50 may be formed in one-time film formation (one-time application) or may be formed in a plurality of times of film formation.

A region (an opening) Jb that is on a side of the memory circuit chip 200b stacked on the sensor substrate 200a, on a side of the logic circuit chip 200c stacked on the sensor substrate 200a, and between the memory circuit chip 200b and the logic circuit chip 200c has a rectangular shape in a cross-sectional view (in the region (the opening) Jb shown in FIG. 2(b), a length of an upper side and a length of a lower side are substantially the same). The SiN film 50 is embedded in the region (the opening) Jb.

As shown in FIG. 2(c), from a second surface of the memory circuit chip 200b opposite a first surface of the memory circuit chip 200b on a side on which the memory circuit chip 200b is stacked on the sensor substrate 200a and a second surface of the logic circuit chip 200c opposite a first surface of the logic circuit chip 200c on a side on which the logic circuit chip 200c is stacked on the sensor substrate 200a, a semiconductor substrate that constitutes the memory circuit 121 and a semiconductor substrate that constitutes the logic circuit 122 are thinned, and the SiN films 50 on the second surface of the memory circuit chip 200b and on the second surface of the logic circuit chip 200c are removed. In addition, thinning the semiconductor substrate that constitutes the memory circuit 121 and the semiconductor substrate that constitutes the logic circuit 122 means that the semiconductor substrate that constitutes the memory circuit 121 and the semiconductor substrate that constitutes the logic circuit 122 are scraped to reduce the thickness.

Therefore, the SiN films 50 are formed on left and right side surfaces of the memory circuit chip 200b connected to the surface of the memory circuit chip 200b on a side on which the memory circuit chip 200b is stacked on the sensor substrate 200a and on left and right side surfaces of the logic circuit chip 200c connected to the surface of the logic circuit chip 200c on a side on which the logic circuit chip 200c is stacked on the sensor substrate 200a. Then, the SiN film 50 is formed to cover the sensor substrate 200a in a region which is on a side of the memory circuit chip 200b on which the memory circuit chip 200b is stacked on the sensor substrate 200a, which is on a side of the logic circuit chip 200c on which the logic circuit chip 200c is stacked on the sensor substrate 200a, in which the sensor substrate 200a and the memory circuit chip 200b are not stacked on each other, and in which the sensor substrate 200a and the logic circuit chip 200c are not stacked on each other.

The SiN film 50 is embedded in a region (an opening) Jc that is on a side of the memory circuit chip 200b stacked on the sensor substrate 200a, on a side of the logic circuit chip 200c stacked on the sensor substrate 200a, and between the memory circuit chip 200b and the logic circuit chip 200c, and the region in which the SiN film 50 is formed has a rectangular shape in a cross-sectional view. That is, the SiN film 50 in the region (the opening) Jc includes a SiN film formed on the right side surface of the memory circuit chip 200b, a SiN film formed on the left side surface of the logic circuit chip 200c, and a SiN film formed to cover the sensor substrate 200a in a region between the right side surface of the memory circuit chip 200b and the left surface of the logic circuit chip 200c.

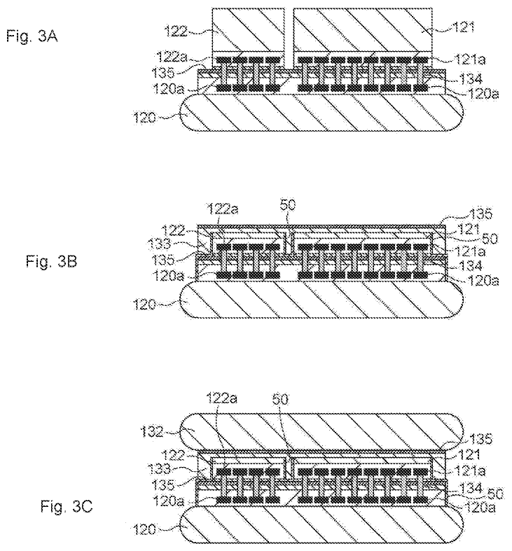

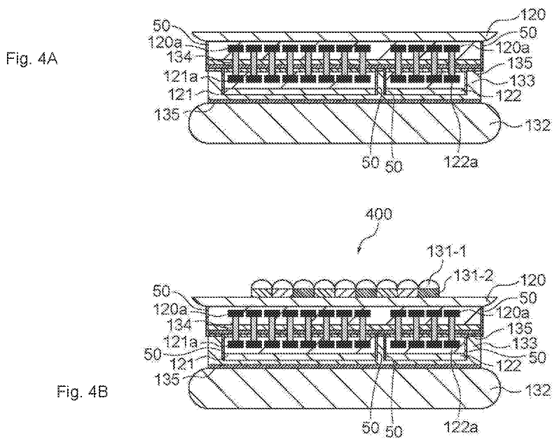

Finally, with reference to FIGS. 3 and 4, the entire method of manufacturing a solid-state imaging device of the first embodiment according to the present technology will be described.

In a first step, as shown in FIG. 3(a), the solid-state imaging element 120 (the sensor substrate) on the wafer is electrically inspected, and then the memory circuit 121 (the memory circuit chip) and logic circuit 122 (the logic circuit chip) which are confirmed to be good products are formed to have a predetermined layout, and the wirings 134 are formed at the terminals 120a and 121a. Further, the wirings 134 from the terminals 121a of the memory circuit 121 and the terminals 122a of the logic circuit 122 and the wirings 134 from the terminals 120a of the solid-state imaging element 120 in the wafer are aligned to appropriately oppose each other and are connected to each other in Cu-Cu connection, and the opposing layers are joined to each other by forming an oxide film joining layer 135 by oxide film joining.

In a second step, as shown in FIG. 3(b), a silicon layer (the semiconductor substrate) on an upper portion of each of the memory circuit 121 and the logic circuit 122 in the drawing is thinned to have a height that does not affect the characteristics of the device, an oxide film 133 that functions as an insulating film is formed, and the memory circuit chip having the memory circuit 121 and the logic chip having the logic circuit 122, which are rearranged, are embedded. The steps shown in FIGS. 2(a) to 2(c) are inserted between the first step (FIG. 3(a)) and the second step (FIG. 3(b)), and the protective film (the SiN film) 50 is formed.

In a third step, as shown in FIG. 3(c), the support substrate 132 is joined to the upper parts of the memory circuit 121 and the logic circuit 122. At this time, the layers in which the support substrate 132, the memory circuit 121, and the logic circuit 122 oppose each other are joined to each other by forming the oxide film joining layer 135 by oxide film joining.

In a fourth step, as shown in FIG. 4(a), the solid-state imaging element 120 is turned upside down to be on an upper side, and the silicon layer (the semiconductor substrate) which is an upper layer of the solid-state imaging element 120 in the drawing is thinned. Thinning the silicon layer (the semiconductor substrate) means cutting the silicon layer (the semiconductor substrate) to reduce the thickness.

In a fifth step, as shown in FIG. 4(b), the on-chip lens 131-1 and the color filter 131-2 are provided on the solid-state imaging element 120 and are separated into individual pieces, and thus a solid-state imaging device 400 is completed. The SiN film 50 is formed to cover the left and right side surfaces of the memory circuit 121 (the memory circuit chip), the left and right side surfaces of the logic circuit 122 (the logic circuit chip), and the solid-state imaging element 120 (the sensor substrate) (in FIG. 4(b), on the left and right side surfaces of the solid-state imaging element 120 (the sensor substrate) and in a downward direction therefrom).

The above-described contents of the solid-state imaging device according to the first embodiment (Example 1 of a solid-state imaging device) of the present technology can be applied to a solid-state imaging device according to a second embodiment of the present technology which will be described later, in particular unless there is a technical contradiction.

### 3. Second Embodiment (Example 2 of Solid-state Imaging Device)

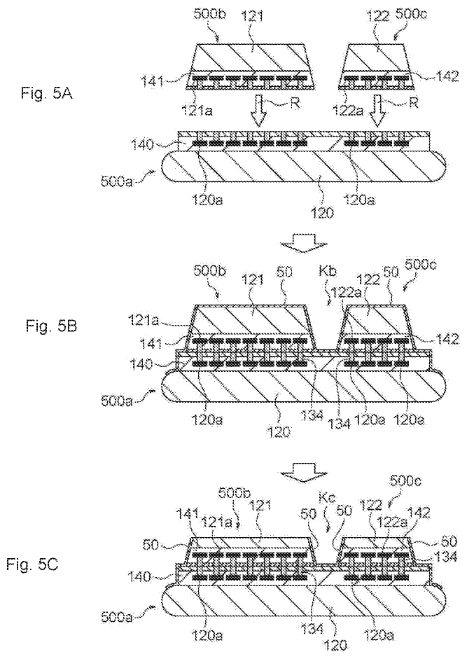

The solid-state imaging device of a second embodiment (Example 2 of the solid-state imaging device) according to the present technology will be described with reference to FIG. 5.

FIG. 5 is a diagram for illustrating the solid-state imaging device and the method of manufacturing a solid-state imaging device of the second embodiment according to the present technology.

FIG. 5(a) shows a state before a sensor substrate 500a including a solid-state imaging element 120 and a wiring layer 140 and a first chip 500b (a memory circuit chip 500b in FIG. 5) including a signal processing circuit (a memory circuit in FIG. 5) 121 and a wiring layer 141 are joined to each other in Cu-Cu (copper copper) joining and shows a state before the sensor substrate 500a including the solid-state imaging element 120 and the wiring layer 140 and a second chip 500c (a logic circuit chip 500c in FIG. 5) including a signal processing circuit (a logic circuit in FIG. 5) 122 and a wiring layer 142 are joined to each other in Cu-Cu (copper-copper) joining. As shown in FIG. 5(a), the sensor substrate 500a and the memory circuit chip 500b are joined to each other in a direction of an arrow R, and similarly, the sensor substrate 500a and the logic circuit chip 500c are joined to each other in the direction of the arrow R.

As shown in FIG. 5(a), the memory circuit chip 500b and the logic circuit chip 500c have a tapered shape in a cross-sectional view (in each chip of the memory circuit chip 500b and the logic circuit chip 500c shown in FIG. 5(a), a length of an upper side is shorter than a length of a lower side).

As shown in FIG. 5(b), the sensor substrate 500a including the solid-state imaging element 120 and the wiring layer 140 and the first chip 500b (the memory circuit chip 500b in FIG. 5) including the signal processing circuit (the memory circuit in FIG. 5) 121 and the wiring layer 141 are electrically connected to each other, and the sensor substrate 500a including the solid-state imaging element 120 and the wiring layer 140 and the second chip 500c (the logic circuit chip 500c in FIG. 5) including a signal processing circuit (the logic circuit in FIG. 5) 122 and the wiring layer 142 are electrically connected to each other.

Specifically, wirings 120a formed in the wiring layer 140 of the sensor substrate 500a and wirings 121a formed in the wiring layer 141 of the memory circuit chip 500b are electrically connected to each other by wirings 134 connected in Cu-Cu (copper-copper) connection, and the wirings 120a formed in the wiring layer 140 of the sensor substrate 500a and wirings 122a formed in the wiring layer 142 of the logic circuit chip 500c are electrically connected to each other by the wirings 134 connected in Cu-Cu (copper-copper) connection.

Then, after the sensor substrate 500a, the memory circuit chip 500b, and the logic chip 500c are joined to each other, the protective film 50 (the SiN film 50 in FIG. 5) is formed to cover the sensor substrate 500a, the memory circuit chip 500b, and the logic circuit chip 500c. The SiN film 50 may be formed in one-time film formation (one-time application) or may be formed in a plurality of times of film formation. Although the SiN film 50 is used in FIG. 5, as long as a material of the protective film 50 has an insulating property and functions as a stopper for contamination with contaminants such as metal contaminants and dust at the time of thinning, which will be described later, the material of the protective film 50 is not limited and may be anything.

As described above, since the memory circuit chip 500b and the logic circuit chip 500c have a tapered shape in a cross-sectional view, a region (an opening) Kb that is on a side of the memory circuit chip 500b stacked on the sensor substrate 500a, on a side of the logic circuit chip 500c stacked on the sensor substrate 500a, and between the memory circuit chip 500b and the logic circuit chip 500c has a reversely tapered shape in a cross-sectional view (in the region (the opening) Kb shown in FIG. 5(b), a length of an upper side is longer than a length of a lower side). The SiN film 50 is embedded in the region (the opening) Kb. Since the region (the opening) Kb has a reversely tapered shape in a cross-sectional view, the upper side of the region (the opening) Kb is more open, and the SiN film 50 is easily embedded.

As shown in FIG. 5(c), from a second surface of the memory circuit chip 500b opposite a first surface of the memory circuit chip 500b on a side on which the memory circuit chip 500b is stacked on the sensor substrate 500a and a second surface of the logic circuit chip 500c opposite a first surface of the logic circuit chip 500c on a side on which the logic circuit chip 500c is stacked on the sensor substrate 500a, a semiconductor substrate that constitutes the memory circuit 121 and a semiconductor substrate that constitutes the logic circuit 122 are thinned, and the SiN films 50 on the second surface of the memory circuit chip 500b and on the second surface of the logic circuit chip 500c are removed. In addition, thinning the semiconductor substrate that constitutes the memory circuit 121 and the semiconductor substrate that constitutes the logic circuit 122 means that the semiconductor substrate that constitutes the memory circuit 121 and the semiconductor substrate that constitutes the logic circuit 122 are scraped to reduce the thickness.

Therefore, the SiN films 50 are formed on left and right side surfaces of the memory circuit chip 500b connected to the surface of the memory circuit chip 500b on a side on which the memory circuit chip 500b is stacked on the sensor substrate 500a and on left and right side surfaces of the logic circuit chip 500c connected to the surface of the logic circuit chip 500c on a side on which the logic circuit chip 500c is stacked on the sensor substrate 500a. Then, the SiN film 50 is formed to cover the sensor substrate 500a in a region which is on a side of the memory circuit chip 500b on which the memory circuit chip 500b is stacked on the sensor substrate 500a, which is on a side of the logic circuit chip 500c on which the logic circuit chip 500c is stacked on the sensor substrate 500a, in which the sensor substrate 500a and the memory circuit chip 500b are not stacked on each other, and in which the sensor substrate 500a and the logic circuit chip 500c are not stacked on each other.

The SiN film 50 is embedded in a region (an opening) Kc that is on a side of the memory circuit chip 500b stacked on the sensor substrate 500a, on a side of the logic circuit chip 500c stacked on the sensor substrate 500a, and between the memory circuit chip 500b and the logic circuit chip 500c, and the region in which the SiN film 50 is formed has a reversely tapered shape in a cross-sectional view. That is, the SiN film 50 in the region (the opening) Kc includes a SiN film formed on the right side surface of the memory circuit chip 500b, a SiN film formed on the left side surface of the logic circuit chip 500c, and a SiN film formed to cover the sensor substrate 500a in a region between the right side surface of the memory circuit chip 500b and the left surface of the logic circuit chip 500c.

Then, as the entire method of manufacturing a solid-state imaging device of the second embodiment according to the present technology, the contents of FIG. 3 and FIG. 4 in which the entire method of manufacturing a solid-state imaging device of the first embodiment according to the present technology has been described can be applied as they are.

The above-described contents of the solid-state imaging device according to the second embodiment (Example 2 of a solid-state imaging device) of the present technology can be applied to the above-described solid-state imaging device according to the first embodiment of the present technology, in particular unless there is a technical contradiction.

### 4. Third Embodiment (Example of Electronic Equipment)

Electronic equipment of a third embodiment according to the present technology is electronic equipment equipped with the solid-state imaging device of any one of the solid-state imaging devices of the first embodiment and the second embodiment according to the present technology.

### 5. Usage Example Solid-state Imaging Device to Which the Present Technology Is Applied

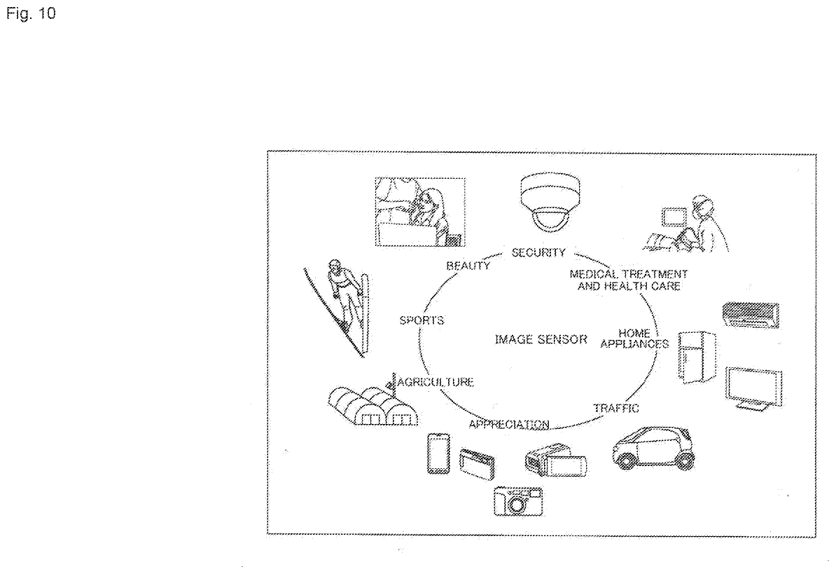

FIG. 10 is a diagram showing a usage example of the solid-state imaging devices of the first and second embodiments according to the present technology as an image sensor.

The above-described solid-state imaging devices according to the first and second embodiments can be used in various cases where light such as visible light, infrared light, ultraviolet light, and X rays is sensed as follows, for example. That is, as shown in FIG. 10, the solid-state imaging device according to any one of the first and second embodiments can be used in devices (for example, the electronic equipment according to the third embodiment described above) which are used in, for example, a field of appreciation in which an image provided for appreciation is captured, a field of traffic, a field of home appliances, a field of medical treatment and health care, a field of security, a field of beauty, a field of sports, and a field of agriculture.

Specifically, in a field of appreciation, the solid-state imaging device according to any one of the first and second embodiments can be used in devices for capturing an image provided for appreciation such as a digital camera, a smartphone, and a mobile phone with a camera function, for example.

In a field of traffic, the solid-state imaging device according to any one of the first and second embodiments can be used in devices provided for traffic such as an in-vehicle sensor that images the front, rear, surroundings, inside, and the like of an automobile, a monitoring camera that monitors traveling vehicles and roads, and a distance measuring sensor that measures a distance between vehicles and the like for safe driving such as automatic stop, recognition of a driver's state, and the like, for example.

In a field of home appliances, the solid-state imaging device according to any one of the first and second embodiments can be used in devices provided for home appliances such as a television receiver, a refrigerator, and an air conditioner, for example, in order to image a user's gesture and operate equipment in response to the gesture.

In a field of medical treatment and health care, the solid-state imaging device according to any one of the first and second embodiments can be used in devices provided for medical treatment and health care such as an endoscope and a device that performs angiography by receiving infrared light, for example.

In a field of security, the solid-state imaging device according to any one of the first and second embodiments can be used in devices provided for security such as a surveillance camera for crime prevention and a camera for person authentication, for example.

In a field of beauty, the solid-state imaging device according to any one of the first and second embodiments can be used in devices provided for beauty such as a skin measuring instrument that images the skin and a microscope that images the scalp, for example.

In a field of sports, the solid-state imaging device according to any one of the first and second embodiments can be used in devices provided for sports such as an action camera and a wearable camera for sports applications, for example.

In a field of agriculture, the solid-state imaging device according to any one of the first and second embodiments can be used in devices provided for agriculture such as a camera that monitors the conditions of fields and crops, for example.

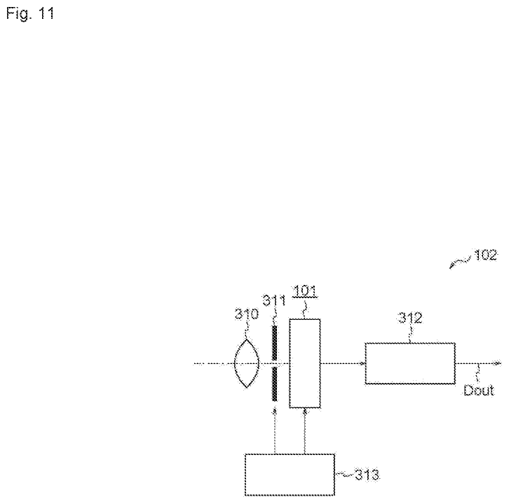

Next, the usage examples of the solid-state imaging devices according to the first and second embodiments of the present technology will be specifically described. For example, as a solid-state imaging device 101, the solid-state imaging device according to any one of the first and second embodiments described above can be applied to any type of electronic equipment equipped with an imaging function, for example, a camera system such as a digital still camera or a video camera, a mobile phone having an imaging function, and the like. As an example, a schematic configuration of electronic equipment 102 (a camera) is shown in FIG. 11. The electronic equipment 102 is, for example, a video camera that can capture a still image or a moving image and includes the solid-state imaging device 101, an optical system (an optical lens) 310, a shutter device 311, a drive unit 313 that drives the solid-state imaging device 101 and the shutter device 311, and a signal processing unit 312.

The optical system 310 guides image light (incident light) from a subject to a pixel portion 101a of the solid-state imaging device 101. This optical system 310 may be constituted by a plurality of optical lenses. The shutter device 311 controls a light irradiation period and a light shielding period for the solid-state imaging device 101. The drive unit 313 controls a transfer operation of the solid-state imaging device 101 and a shutter operation of the shutter device 311. The signal processing unit 312 performs various types of signal processing on signals output from the solid-state imaging device 101. A video signal Dout after signal processing is stored in a storage medium such as a memory or is output to a monitor or the like.

### 6. Application Example to Endoscopic Surgery System

The present technology can be applied to various products. For example, the technology according to the present disclosure (the present technology) may be applied to an endoscopic surgery system.

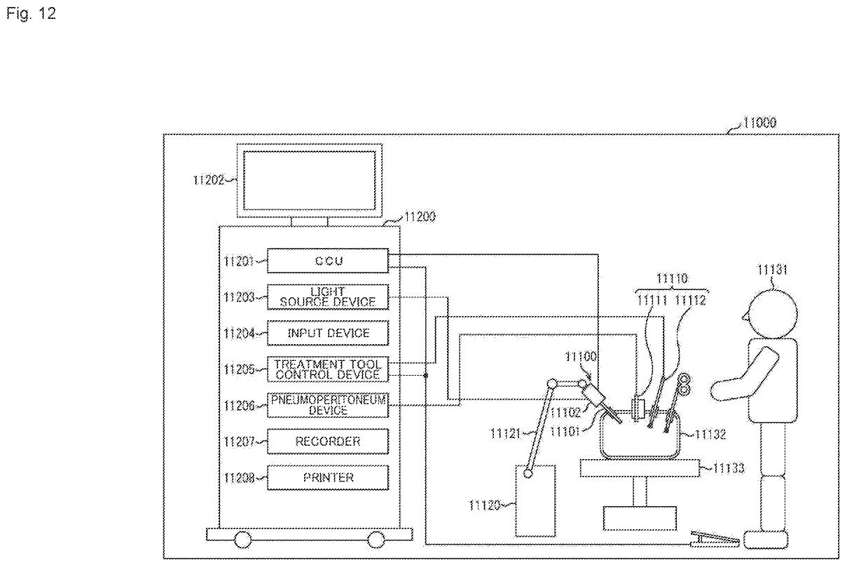

FIG. 12 is a diagram showing an example of a schematic configuration of an endoscopic surgery system to which the technology according to the present disclosure (the present technology) can be applied.

FIG. 12 shows a state where a surgeon (a doctor) 11131 is performing a surgical operation on a patient 11132 on a patient bed 11133 using an endoscopic surgery system 11000. As shown in the drawing, the endoscopic surgery system 11000 includes an endoscope 11100, other surgical instruments 11110 such as a pneumoperitoneum tube 11111 and an energized treatment tool 11112, a support arm device 11120 that supports the endoscope 11100, and a cart 11200 equipped with various devices for endoscopic surgery.

The endoscope 11100 includes a lens barrel 11101, a region of which having a predetermined length from a distal end is inserted into a body cavity of the patient 11132 and a camera head 11102 connected to a proximal end of the lens barrel 11101. Although the endoscope 11100 configured as a so-called rigid mirror having the rigid lens barrel 11101 is shown in the shown example, the endoscope 11100 may be configured as a so-called flexible mirror having a flexible lens barrel.

An opening in which an objective lens is fitted is provided at the distal end of the lens barrel 11101. A light source device 11203 is connected to the endoscope 11100, and light generated by the light source device 11203 is guided to the distal end of the lens barrel by a light guide extending inside the lens barrel 11101 and is radiated toward the observation target in the body cavity of the patient 11132 via the objective lens. The endoscope 11100 may be a direct-viewing endoscope or may be a perspective endoscope or a side-viewing endoscope.

An optical system and an imaging element are provided inside the camera head 11102, and the reflected light (observation light) from the observation target converges on the imaging element by the optical system. The observation light is photoelectrically converted by the imaging element, and an electrical signal corresponding to the observation light, that is, an image signal corresponding to an observation image is generated. The image signal is transmitted as RAW data to a camera control unit (CCU) 11201.

The CCU 11201 is constituted by a central processing unit (CPU), a graphics processing unit (GPU), and the like and comprehensively controls the operation of the endoscope 11100 and a display device 11202. In addition, the CCU 11201 receives an image signal from the camera head 11102 and performs various types of image processing for displaying an image based on the image signal, for example, development processing (demosaic processing) on the image signal.

The display device 11202 displays an image based on an image signal having been subjected to image processing by the CCU 11201 under the control of the CCU 11201.

The light source device 11203 is constituted by, for example, a light source such as a light emitting diode (LED) and supplies radiation light at the time of imaging a surgical site or the like to the endoscope 11100.

An input device 11204 is an input interface for the endoscopic surgery system 11000. The user can input various types of information or instructions to the endoscopic surgery system 11000 via the input device 11204. For example, the user inputs an instruction to change imaging conditions (a type of radiation light, a magnification, a focal length, or the like) of the endoscope 11100.

A treatment tool control device 11205 controls the driving of the energized treatment tool 11112 for cauterizing or incising tissue, sealing a blood vessel, or the like. In order to secure a field of view of the endoscope 11100 and secure an operation space of the surgeon, a pneumoperitoneum device 11206 sends gas into the body cavity of the patient 11132 via the pneumoperitoneum tube 11111 in order to inflate the body cavity. A recorder 11207 is a device that can record various types of information related to surgery. A printer 11208 is a device that can print various types of information related to surgery in various formats such as text, images and graphs.

The light source device 11203 that supplies the endoscope 11100 with the radiation light for imaging the surgical site can be configured of, for example, an LED, a laser light source, or a white light source configured of a combination thereof. When a white light source is formed by a combination of RGB laser light sources, it is possible to control an output intensity and an output timing of each color (each wavelength) with high accuracy, and thus the light source device 11203 can adjust white balance of the captured image. Further, in this case, laser light from each of the respective RGB laser light sources is radiated to the observation target in a time division manner, and driving of the imaging element of the camera head 11102 is controlled in synchronization with radiation timing such that images corresponding to respective RGB can be captured in a time division manner. According to this method, it is possible to obtain a color image without providing a color filter to the imaging element.

Further, the driving of the light source device 11203 may be controlled to change the intensity of output light at predetermined time intervals. The driving of the imaging element of the camera head 11102 is controlled in synchronization with the timing of the change in the light intensity to acquire an image in a time division manner, and the image is synthesized, whereby it is possible to generate a so-called image in a high dynamic range without underexposure or overexposure.

In addition, the light source device 11203 may have a configuration in which light in a predetermined wavelength band corresponding to special light observation can be supplied. In the special light observation, for example, by emitting light in a band narrower than that of radiation light (that is, white light) during normal observation using wavelength dependence of light absorption in a body tissue, so-called narrow band light observation (narrow band imaging) in which a predetermined tissue such as a blood vessel in a mucous membrane surface layer is imaged with a high contrast is performed. Alternatively, in the special light observation, fluorescence observation in which an image is obtained by fluorescence generated by emitting excitation light may be performed. The fluorescence observation can be performed by emitting excitation light to a body tissue and observing fluorescence from the body tissue (autofluorescence observation), or locally injecting a reagent such as indocyanine green (ICO) to a body tissue and emitting excitation light corresponding to a fluorescence wavelength of the reagent to the body tissue to obtain a fluorescence image. The light source device 11203 may have a configuration in which narrow band light and/or excitation light corresponding to such special light observation can be supplied.

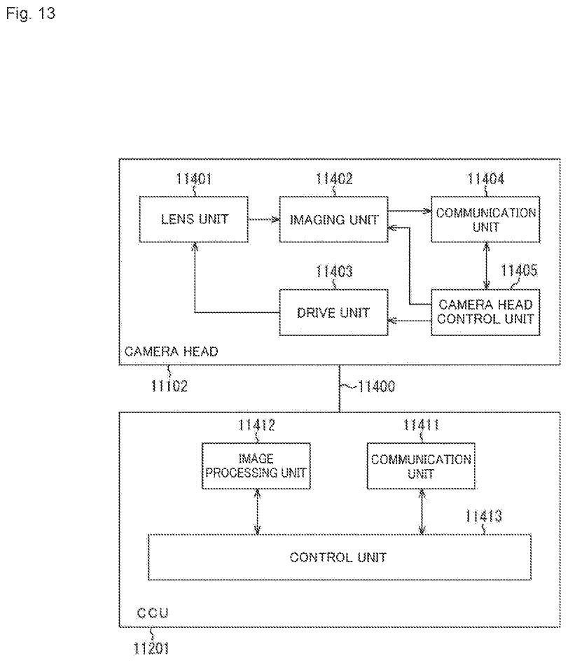

FIG. 13 is a block diagram showing an example of a functional configuration of the camera head 11102 and the CCU 11201 shown in FIG. 12.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are connected to each other such that they can communicate with each other via a transmission cable 11400.

The lens unit 11401 is an optical system provided at a portion for connection to the lens barrel 11101. Observation light taken from the tip of the lens barrel 11101 is guided to the camera head 11102 and is incident on the lens unit 11401. The lens unit 11401 is constituted by a combination of a plurality of lenses including a zoom lens and a focus lens.

The imaging unit 11402 is constituted by an imaging element. The imaging element constituting the imaging unit 11402 may be one element (a so-called single plate type) or a plurality of elements (a so-called multi-plate type). When the imaging unit 11402 is configured as a multi-plate type, for example, image signals corresponding to RGB are generated by the imaging elements, and a color image may be obtained by synthesizing the image signals. Alternatively, the imaging unit 11402 may be configured to include a pair of imaging elements for acquiring image signals for the right eye and the left eye corresponding to three-dimensional (3D) display. When 3D display is performed, the surgeon 11131 can ascertain the depth of biological tissues in the surgical site more accurately. Here, when the imaging unit 11402 is configured as a multi-plate type, a plurality of lens units 11401 may be provided according to the imaging elements.

Further, the imaging unit 11402 may not necessarily be provided in the camera head 11102. For example, the imaging unit 11402 may be provided immediately after the objective lens inside the lens barrel 11101.

The drive unit 11403 is constituted by an actuator and moves the zoom lens and the focus lens of the lens unit 11401 by a predetermined distance along an optical axis under the control of the camera head control unit 11405. Thereby, the magnification and the focus of the image captured by the imaging unit 11402 can be appropriately adjusted.

The communication unit 11404 is constituted by a communication device for transmitting or receiving various types of information to or from the CCU 11201. The communication unit 11404 transmits the image signal obtained from the imaging unit 11402 as RAW data to the CCU 11201 via the transmission cable 11400.

In addition, the communication unit 11404 receives a control signal for controlling driving of the camera head 11102 from the CCU 11201 and supplies the control signal to the camera head control unit 11405. The control signal includes, for example, information on the imaging conditions such as information indicating that the frame rate of the captured image is designated, information indicating that the exposure value at the time of imaging is designated, and/or information indicating that the magnification and the focus of the captured image are designated.

The imaging conditions such as the frame rate, the exposure value, the magnification, and the focus may be appropriately designated by the user, or may be automatically set by the control unit 11413 of the CCU 11201 on the basis of the acquired image signal. In the latter case, a so-called auto exposure (AE) function, a so-called auto focus (AF) function, and a so-called auto white balance (AWB) function are provided in the endoscope 11100.

The camera head control unit 11405 controls the driving of the camera head 11102 on the basis of the control signal from the CCU 11201 received via the communication unit 11404.

The communication unit 11411 is constituted by a communication device for transmitting and receiving various types of information to and from the camera head 11102. The communication unit 11411 receives the image signal transmitted from the camera head 11102 via the transmission cable 11400.

In addition, the communication unit 11411 transmits a control signal for controlling the driving of the camera head 11102 to the camera head 11102. The image signal or the control signal can be transmitted through electric communication, optical communication, or the like.

The image processing unit 11412 performs various types of image processing on the image signal which is the RAW data transmitted from the camera head 11102.

The control unit 11413 performs various kinds of control regarding the imaging of the surgical site or the like using the endoscope 11100 and a display of a captured image obtained by imaging the surgical site or the like. For example, the control unit 11413 generates the control signal for controlling the driving of the camera head 11102.

Further, the control unit 11413 causes the display device 11202 to display the captured image obtained by imaging the surgical site or the like on the basis of the image signal having subjected to the image processing by the image processing unit 11412. In this case, the control unit 11413 may recognize various objects in the captured image using various image recognition technologies. For example, the control unit 11413 can recognize surgical instruments such as forceps, a specific biological part, bleeding, mist when the energized treatment tool 11112 is used, and the like by detecting the edge shape and color of the object included in the captured image. When the control unit 11413 causes the display device 11202 to display the captured image, it may cause various types of surgical support information to be superimposed and displayed with the image of the surgical site using the recognition result. When the surgical support information is superimposed and displayed and is presented to the surgeon 11131, it is possible to reduce the burden on the surgeon 11131, and the surgeon 11131 can reliably proceed the surgery.

The transmission cable 11400 connecting the camera head 11102 and the CCU 11201 to each other is an electric signal cable that deals with electric signal communication, an optical fiber that deals with optical communication, or a composite cable thereof.

Here, in the example shown in the drawing, communication is performed in a wired manner using the transmission cable 11400, but communication between the camera head 11102 and the CCU 11201 may be performed in a wireless manner.

The example of the endoscopic surgery system to which the technology according to the present disclosure can be applied has been described above. The technology according to the present disclosure can be applied to the endoscope 11100, the camera head 11102 (the imaging unit 11402 thereof), or the like among the configurations described above. Specifically, the solid-state imaging device 111 of the present disclosure can be applied to the imaging unit 10402. By applying the technology according to the present disclosure to the endoscope 11100, the camera head 11102 (the imaging unit 11402 thereof), or the like, it is possible to improve the quality and reliability of the endoscope 11100, the camera head 11102 (the imaging unit 11402 thereof), or the like.

While the endoscopic surgery system has been described here as an example, the technology according to the present disclosure may be applied to other systems, for example, a microscopic surgery system.

### 7. Application Example to Moving Body

The technology according to the present disclosure (the present technology) can be applied to various products. For example, the technology according to the present disclosure may be realized as a device equipped in any type of moving body such as an automobile, an electric vehicle, a hybrid electric vehicle, a motorcycle, a bicycle, a personal mobility device, an airplane, a drone, a ship, and a robot.

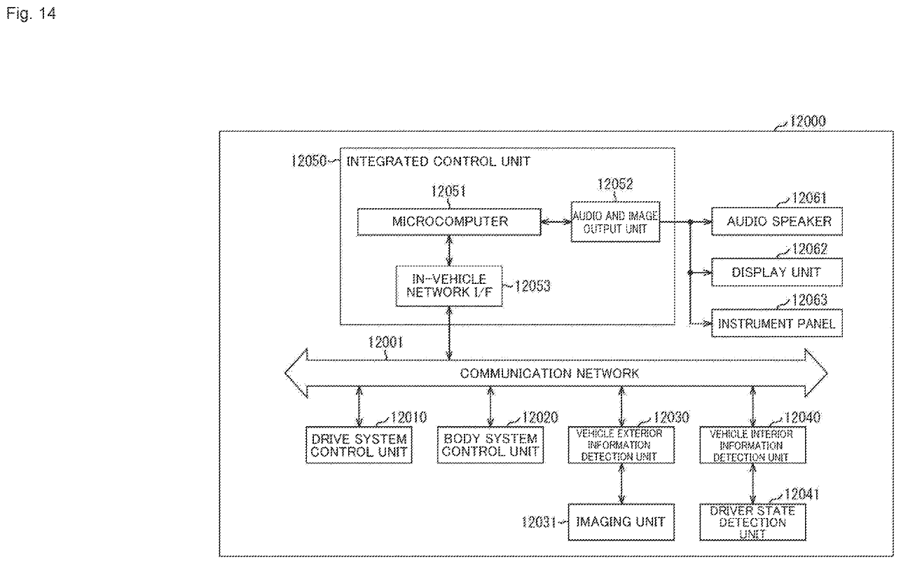

FIG. 14 is a block diagram showing a schematic configuration example of a vehicle control system which is an example of a moving body control system to which the technology according to the present disclosure can be applied.

The vehicle control system 12000 includes a plurality of electronic control units connected thereto via a communication network 12001. In the example illustrated in FIG. 14, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, an audio and image output unit 12052, and an in-vehicle network interface (I/F) 12053 are shown.

The drive system control unit 12010 controls operations of devices related to a drive system of a vehicle according to various programs. For example, the drive system control unit 12010 functions as a control device such as a driving force generation device for generating a driving force of a vehicle such as an internal combustion engine or a driving motor, a driving force transmission mechanism for transmitting a driving force to wheels, a steering mechanism for adjusting a turning angle of a vehicle, and a braking device for generating a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle equipped with the vehicle control system 12000. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or ranging information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the outside and the inside of the vehicle acquired by the vehicle exterior information detection unit 12030 and the vehicle interior information detection unit 12040 and output a control command to the drive system control unit 12010. For example, the microcomputer 12051 can perform cooperative control for the purpose of realizing functions of an advanced driver assistance system (ADAS) including collision avoidance or impact mitigation of a vehicle, following traveling based on inter-vehicle distance, vehicle speed maintenance driving, vehicle collision warning, vehicle lane deviation warning, or the like.

Further, the microcomputer 12051 can perform cooperative control for the purpose of automated driving or the like in which autonomous travel is performed without depending on operations of the driver by controlling the driving force generation device, the steering mechanism, the braking device, or the like on the basis of information on the surroundings of the vehicle acquired by the vehicle exterior information detection unit 12030 or the vehicle interior information detection unit 12040.

In addition, the microcomputer 12051 can output a control command to the body system control unit 12020 on the basis of the information on the outside of the vehicle acquired by the vehicle exterior information detection unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The audio and image output unit 12052 transmits an output signal of at least one of an audio and an image to an output device capable of visually or audibly notifying an occupant of a vehicle or the outside of the vehicle of information. In the example of FIG. 14, an audio speaker 12061, a display unit 12062, and an instrument panel 12063 are illustrated as the output device. The display unit 12062 may include, for example, at least one of an onboard display and a head-up display.

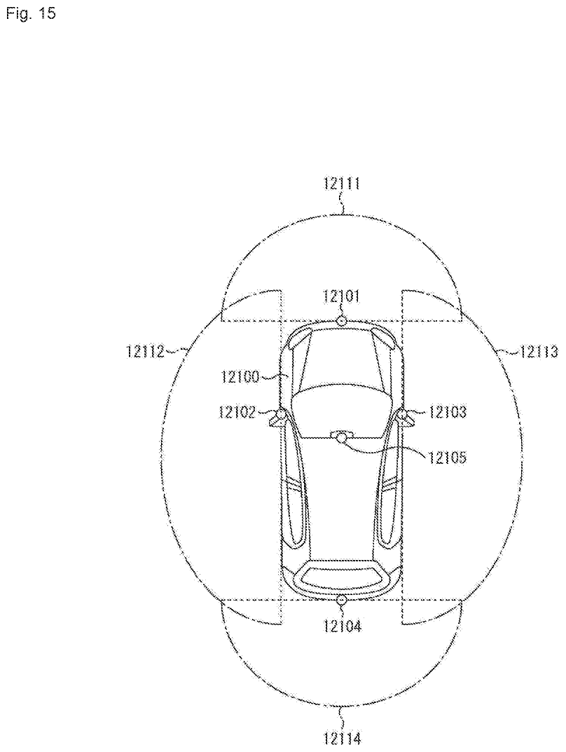

FIG. 15 is a diagram showing an example of an installation position of the imaging unit 12031.

In FIG. 15, a vehicle 12100 includes imaging units 12101, 12102, 12103, 12104, and 12105 as the imaging unit 12031.

The imaging units 12101, 12102, 12103, 12104, and 12105 may be provided at positions such as a front nose, side-view mirrors, a rear bumper, a back door, and an upper portion of a windshield in a vehicle interior of the vehicle 12100, for example. The imaging unit 12101 provided on the front nose and the imaging unit 12105 provided in the upper portion of the windshield in the vehicle interior mainly acquire images of a side in front of the vehicle 12100. The imaging units 12102 and 12103 provided on the side-view mirrors mainly acquire images of lateral sides from the vehicle 12100. The imaging unit 12104 provided on the rear bumper or the back door mainly acquires images of a side behind the vehicle 12100. The images of a side in front of the vehicle which are acquired by the imaging units 12101 and 12105 are mainly used for detection of preceding vehicles, pedestrians, obstacles, traffic signals, traffic signs, lanes, and the like.

FIG. 15 shows an example of imaging ranges of the imaging units 12101 to 12104. An imaging range 12111 indicates the imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, a bird's-eye view image of the vehicle 12100 as viewed from above can be obtained by superimposition of image data captured by the imaging units 12101 to 12104.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path along which the vehicle 12100 is traveling, which is a three-dimensional object traveling at a predetermined speed (for example, 0 km/h or higher) in the substantially same direction as the vehicle 12100, as a preceding vehicle by acquiring a distance to each of three-dimensional objects in the imaging ranges 12111 to 12114 and temporal change in the distance (a relative speed with respect to the vehicle 12100) on the basis of the distance information obtained from the imaging units 12101 to 12104. Further, the microcomputer 12051 can set an inter-vehicle distance which should be secured in front of the vehicle in advance with respect to the preceding vehicle and can perform automated brake control (also including following stop control) or automated acceleration control (also including following start control). In this way, it is possible to perform cooperative control for the purpose of automated driving or the like in which a vehicle autonomously travels without depending on operations of the driver.

For example, the microcomputer 12051 can classify and extract three-dimensional object data regarding three-dimensional objects into two-wheeled vehicles, ordinary vehicles, large vehicles, pedestrians, and other three-dimensional objects such as utility poles on the basis of the distance information obtained from the imaging units 12101 to 12104 and can use the three-dimensional object data for automatic avoidance of obstacles. For example, the microcomputer 12051 identifies obstacles in the vicinity of the vehicle 12100 into obstacles that can be visually recognized by the driver of the vehicle 12100 and obstacles that are difficult to be visually recognized by the driver. Then, the microcomputer 12051 can determine a risk of collision indicating the degree of risk of collision with each obstacle and can perform driving assistance for collision avoidance by outputting a warning to the driver through the audio speaker 12061 or the display unit 12062 and performing forced deceleration or avoidance steering through the drive system control unit 12010 when the risk of collision has a value equal to or greater than a set value and there is a possibility of collision.

At least one of the imaging units 12101 to 12104 may be an infrared camera that detects infrared rays. For example, the microcomputer 12051 can recognize a pedestrian by determining whether there is a pedestrian in the captured images of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating the outline of the object and it is determined whether the object is a pedestrian. When the microcomputer 12051 determines that there is a pedestrian in the captured images of the imaging units 12101 to 12104, and the pedestrian is recognized, the audio and image output unit 12052 controls the display unit 12062 such that the recognized pedestrian is superimposed and displayed with a square contour line for emphasis. In addition, the audio and image output unit 12052 may control the display unit 12062 such that an icon or the like indicating a pedestrian is displayed at a desired position.

An example of the vehicle control system to which the technology according to the present disclosure (the present technology) can be applied has been described above. The technology according to the present disclosure may be applied, for example, to the imaging unit 12031 or the like among the configurations described above. Specifically, the solid-state imaging device 111 of the present disclosure can be applied to the imaging unit 12031. By applying the technology according to the present disclosure to the imaging unit 12031, it is possible to improve the quality and reliability of the imaging unit 12031.

The present technology are not limited to the above-described embodiments, usage examples, and application examples, and various changes can be made without departing from the gist of the present technology.

Furthermore, the effects described in the present specification are merely exemplary and not intended to be limited, and other effects may be provided as well.

In addition, the present technology can also adopt the following configurations.

[1] A solid-state imaging device including:

a sensor substrate having an imaging element that generates a pixel signal in a pixel unit; and

at least one chip having a signal processing circuit necessary for signal processing of the pixel signal,

wherein the sensor substrate and the at least one chip are electrically connected to and stacked on each other, and

wherein a protective film is formed on at least a part of a side surface of the at least one chip, the side surface being connected to a surface of the at least one chip on a side on which the at least one chip is stacked on the sensor substrate.

[2] The solid-state imaging device according to [1], wherein the protective film is formed to cover the sensor substrate in a region which is on a side of the at least one chip on which the at least one chip is stacked on the sensor substrate and in which the sensor substrate and the at least one chip are not stacked on each other.

[3] The solid-state imaging device according to [1] or [2], wherein the protective film is formed to cover an outer periphery of the at least one chip in a plan view from a side of the at least one chip.

[4] The solid-state imaging device according to any one of [1] to [3],

wherein the at least one chip is constituted by a first chip and a second chip,

wherein the first chip and the sensor substrate are electrically connected to and stacked on each other,

wherein the second chip and the sensor substrate are electrically connected to and stacked on each other,

wherein a protective film is formed on at least a part of a side surface of the first chip, the side surface being connected to a surface of the first chip on a side on which the first chip is stacked on the sensor substrate, and

wherein a protective film is formed on at least a part of a side surface of the second chip, the side surface being connected to a surface of the second chip on a side on which the second chip is stacked on the sensor substrate.

[5] The solid-state imaging device according to [4],

wherein the first chip and the second chip are stacked in the same direction on the sensor substrate, and

wherein the protective film is formed to cover the sensor substrate in a region which is on a side of the first chip on which the first chip is stacked on the sensor substrate, which is on a side of the second chip on which the second chip is stacked on the sensor substrate, in which the sensor substrate and the first chip are not stacked on each other, and in which the sensor substrate and the second chip are not stacked on each other.

[6] The solid-state imaging device according to [4] or [5],

wherein the first chip and the second chip are stacked in the same direction on the sensor substrate, and

wherein the protective film is formed to cover an outer periphery of the first chip and an outer periphery of the second chip in a plan view from a side of the first chip and a side of the second chip.

[7] The solid-state imaging device according to any one of [4] to [6],

wherein the first chip and the second chip are stacked in the same direction on the sensor substrate,

wherein the protective film is formed in a region which is on a side of the first chip on which the first chip is stacked on the sensor substrate, which is on a side of the second chip on which the second chip is stacked on the sensor substrate, and which is between the first chip and the second chip, and

wherein the region on which the protective film is formed is rectangular in a cross-sectional view from a side of the first chip and a side of the second chip.

[8] The solid-state imaging device according to any one of [4] to [6],

wherein the first chip and the second chip are stacked in the same direction on the sensor substrate,

wherein the protective film is formed in a region which is on a side of the first chip on which the first chip is stacked on the sensor substrate, which is on a side of the second chip on which the second chip is stacked on the sensor substrate, and which is between the first chip and the second chip, and

wherein the region on which the protective film is formed has a reversely tapered shape in a cross-sectional view from a side of the first chip and a side of the second chip.

[9] The solid-state imaging device according to any one of [1] to [8], wherein the protective film is formed by a single film formation.

[10] The solid-state imaging device according to any one of [1] to [9], wherein the protective film contains a material having an insulating property.

[11] The solid-state imaging device according to any one of [1] to [10], wherein the protective film contains silicon nitride.

[12] Electronic equipment equipped with the solid-state imaging device according to any one of [1] to [11].

[13] A method of manufacturing a solid-state imaging device including at least: stacking a sensor substrate having an imaging element that generates a pixel signal in a pixel unit and at least one chip having a signal processing circuit necessary for signal processing of the pixel signal to be electrically connected to each other;

forming a protective film to cover the at least one chip after the stacking; and

thinning the at least one chip from a second surface of the at least one chip opposite a first surface of the at least one chip on a side on which the at least one chip is stacked on the sensor substrate to remove the protective film on the second surface.

[14] The method of manufacturing a solid-state imaging device according to [13], including forming the protective film to cover the at least one chip and the sensor substrate after the stacking.

### REFERENCE SIGNS LIST

50 Protective film (SiN film)

100a, 200a, 500a, 600a, 900a Sensor substrate

100b, 200b, 500b, 600b, 900b First chip (memory circuit chip)

100c, 200c, 500c, 600c, 900c Second chip (logic circuit chip)

400, 600, 700, 800 Solid-state imaging device

1. A solid-state imaging device comprising:
a sensor substrate having an imaging element that generates a pixel signal in a pixel unit; and
at least one chip having a signal processing circuit necessary for signal processing of the pixel signal,
wherein the sensor substrate and the at least one chip are electrically connected to and stacked on each other, and
wherein a protective film is formed on at least a part of a side surface of the at least one chip, the side surface being connected to a surface of the at least one chip on a side on which the at least one chip is stacked on the sensor substrate.

2. The solid-state imaging device according to claim 1, wherein the protective film is formed to cover the sensor substrate in a region which is on a side of the at least one chip on which the at least one chip is stacked on the sensor substrate and in which the sensor substrate and the at least one chip are not stacked on each other.

3. The solid-state imaging device according to claim 1, wherein the protective film is formed to cover an outer periphery of the at least one chip in a plan view from a side of the at least one chip.

4. The solid-state imaging device according to claim 1,
wherein the at least one chip is constituted by a first chip and a second chip,
wherein the first chip and the sensor substrate are electrically connected to and stacked on each other,
wherein the second chip and the sensor substrate are electrically connected to and stacked on each other,
wherein a protective film is formed on at least a part of a side surface of the first chip, the side surface being connected to a surface of the first chip on a side on which the first chip is stacked on the sensor substrate, and
wherein a protective film is formed on at least a part of a side surface of the second chip, the side surface being connected to a surface of the second chip on a side on which the second chip is stacked on the sensor substrate.

5. The solid-state imaging device according to claim 4,
wherein the first chip and the second chip are stacked in the same direction on the sensor substrate, and
wherein the protective film is formed to cover the sensor substrate in a region which is on a side of the first chip on which the first chip is stacked on the sensor substrate, which is on a side of the second chip on which the second chip is stacked on the sensor substrate, in which the sensor substrate and the first chip are not stacked on each other, and in which the sensor substrate and the second chip are not stacked on each other.

6. The solid-state imaging device according to claim 4,
wherein the first chip and the second chip are stacked in the same direction on the sensor substrate, and
wherein the protective film is formed to cover an outer periphery of the first chip and an outer periphery of the second chip in a plan view from a side of the first chip and a side of the second chip.

7. The solid-state imaging device according to claim 4,
wherein the first chip and the second chip are stacked in the same direction on the sensor substrate,
wherein the protective film is formed in a region which is on a side of the first chip on which the first chip is stacked on the sensor substrate, which is on a side of the second chip on which the second chip is stacked on the sensor substrate, and which is between the first chip and the second chip, and
wherein the region on which the protective film is formed is rectangular in a cross-sectional view from a side of the first chip and a side of the second chip.

8. The solid-state imaging device according to claim 4,
wherein the first chip and the second chip are stacked in the same direction on the sensor substrate,
wherein the protective film is formed in a region which is on a side of the first chip on which the first chip is stacked on the sensor substrate, which is on a side of the second chip on which the second chip is stacked on the sensor substrate, and which is between the first chip and the second chip, and
wherein the region on which the protective film is formed has a reversely tapered shape in a cross-sectional view from a side of the first chip and a side of the second chip.

9. The solid-state imaging device according to claim 1, wherein the protective film is formed by a single film formation.

10. The solid-state imaging device according to claim 1, wherein the protective film contains a material having an insulating property.

11. The solid-state imaging device according to claim 1, wherein the protective film contains silicon nitride.

12. Electronic equipment equipped with the solid-state imaging device according to claim 1.

13. A method of manufacturing a solid-state imaging device comprising at least:
stacking a sensor substrate having an imaging element that generates a pixel signal in a pixel unit and at least one chip having a signal processing circuit necessary for signal processing of the pixel signal to be electrically connected to each other;
forming a protective film to cover the at least one chip after the stacking; and
thinning the at least one chip from a second surface of the at least one chip opposite a first surface of the at least one chip on a side on which the at least one chip is stacked on the sensor substrate to remove the protective film on the second surface.

14. The method of manufacturing a solid-state imaging device according to claim 13, comprising forming the protective film to cover the at least one chip and the sensor substrate after the stacking.
